(19) United States
(12) Patent Application Publication
(10) Pub. No.: US 2009/0142916 A1
(43) Pub. Date: Jun. 4, 2009

(54) APPARATUS AND METHOD OF MANUFACTURING AN INTEGRATED CIRCUIT

(75) Inventors: Heike Prenz, Dresden (DE); Peter Thieme, Pesterwitz (DE); Peter Lahnor, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/947,578

(22) Filed: Nov. 29, 2007

(51) Int. Cl. H01L 21/44; H01B 13/00; B23H 3/02; H01L 21/302; H01L 21/306; C25B 9/00

(52) U.S. Cl. 438/598; 216/13; 205/640; 156/345.15; 156/345.54; 204/275.1; 438/692

(57) ABSTRACT

On aspect is a method to manufacture an integrated circuit including a reshaping process of the wafer edge region and an apparatus to perform the reshaping process.

### BACKGROUND

Cost effective processing of integrated circuits formed on a semiconductor wafer requires full functionality of the components over the available top surface of the wafer. Major efforts have been made to minimize process variations over the wafer area, for example, in the region close to the wafer edge. An industry specification requires yielding integrated circuit components which are fully located inside an area reaching from the wafer center out to an edge exclusion of 2 mm, with a target being extended to an edge exclusion of 1.5 mm in the near future. In order to accomplish this target, it is important to control each parameter influencing the result of every processing step. One realization is that the shape of the wafer edge is one of those parameters, since a plurality of process steps are influenced by this shape. The precise shape of the wafer edge is initially defined by the wafer material supplier, but also modified during the course of processing steps, resulting in a need to actively control and/or adapt to this shape.

### SUMMARY

One embodiment includes a method of manufacturing an integrated circuit. One process includes processing a wafer with an edge region having a first shape to a first manufacturing stage. The process also includes reshaping the wafer to transform the wafer edge region into a second shape, and processing the wafer to a second manufacturing stage.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

The accompanying drawings are included to provide a further understanding of embodiments and are incorporated in and constitute a part of the specification. The drawings illustrate embodiments and together with the description serve as explanation. Other embodiments and many of the intended advantages will be readily appreciated as they become better understood by reference to the following detailed description. The elements of the drawings are not necessarily to scale relative to each other. Like reference numerals designate corresponding similar parts.

FIG. 1 illustrates a schematic cross section of a wafer's edge region.

FIG. 2 illustrates wafer shape profiles before and after performing a reshaping operation.

FIGS. 3a, 3b illustrate modifications to the wafer shape introduced during the manufacturing process.

FIGS. 4 to 6 show process flows in accordance with an embodiment.

FIG. 7 illustrate a controlling scheme according to an embodiment.

FIG. 8 illustrate schematics of a chemical mechanical polishing setup according to another embodiment.

FIG. 9 illustrates components of a wafer bevel shaping apparatus according to another embodiment.

FIGS. 10a and 10b show the result of a split experiment using wafers with and without a modified edge shape.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

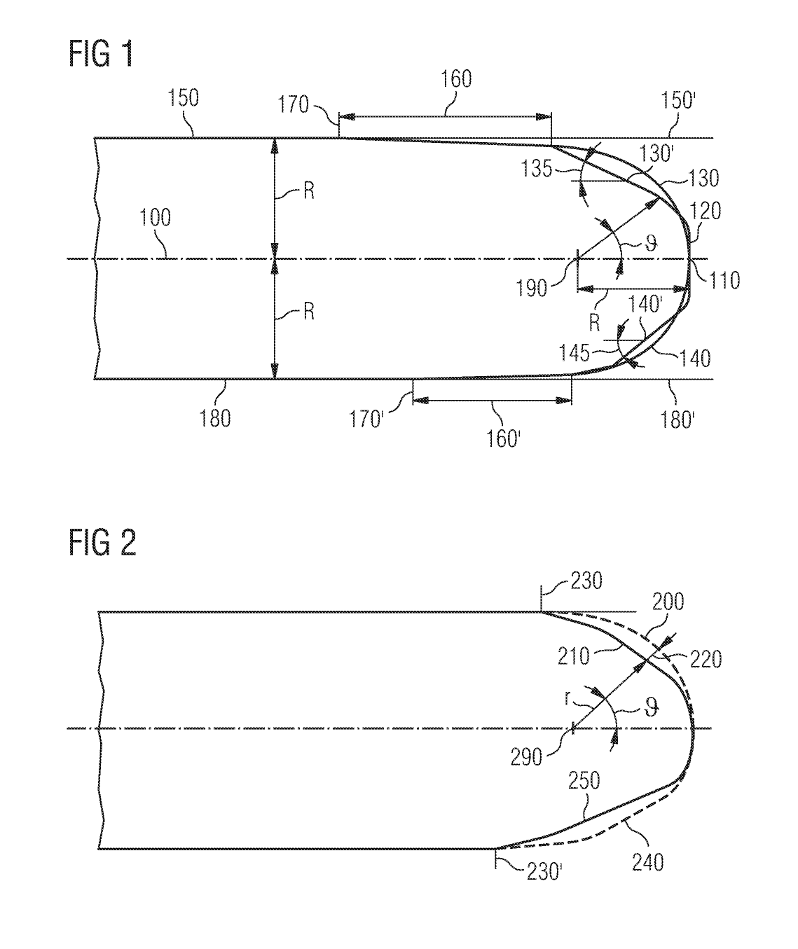

FIG. 1 illustrates a cross-sectional view of a wafer. The upper surface of the wafer 150 defines the side used to form the functional components, and is essentially flat with the projection 150′ extending outside and defining a horizontal upper surface plane. The wafer backside 180 (including its projection 180′) usually does not contain functional components and runs in parallel to the upper surface 150. The reference plane 100 is located in the center between the upper surface 150 and the wafer backside 180 and intersects with the wafer surface at the outer wafer edge 110, thus defining the wafer perimeter.

The shape of the wafer edge can be separated in several regions. Adjacent to the upper surface 150, the roll off region 160, 160′ is a region, in which the wafer surface deviates gradually from the projection 150′. This region may extend between approximately 0.5 mm and 2-5 mm from the outer wafer edge. Therefore, functional components may be located within the roll off region 160. In the upper bevel region 130 and the lower bevel region 140 the slope of the shape relative to the horizontal reference plane 100 increases compared to the roll off region 160, 160′, with a smooth transition between the regions.

In one type of commercially available wafers, called blunt type wafers, the slope remains essentially constant within the bevel region thereby forming an inclined facet 130′, 140′ relative to the reference plane 100 with an upper facet angle 135 and a lower facet angle 145, which may be equal or different from each other. Another type of commercially available wafers, called round type, includes a bevel region 130, 140 with continuously varying curvature and no such facet. The apex region 120 is disposed between the upper bevel region 130, 130′ and the lower bevel region 140, 140′. The wafer shape runs essentially vertical within the apex region 120 with some curvature to form a smooth transition to the adjacent bevel region 130, 130′, 140, 140′.

In order to parameterize the wafer shape, one may define a reference point 190 in the cross-sectional view being located in the reference plane at a distance from the outer wafer edge 110 equal to the distance R between the reference plane 100 and the upper surface 150 (or the wafer backside 180). The distance r from this reference point to the wafer surface can be determined as a function of the angle □ as illustrated in FIG. 1. The shape of the wafer may be symmetrical to the reference plane 100, or differ between the region above and below the reference plane 100.

The wafer shape has a direct impact on the process performance of various types of manufacturing processes. Some exemplary mechanisms are described in the following, leading to an influence of the wafer shape to the process performance, but embodiments are not be limited by these examples, and it is possible for other processes and other mechanisms to be effective, as well.

One example of such a process is chemical-mechanical polishing (CMP). A wafer is pressed with the upper surface 150 against a polishing pad through a wafer carrier comprising a retaining ring. The pad is moved relative to the wafer, so that the pad portion, which enters the contact region between the pad and the carrier with the wafer, first contacts the retaining ring, and then makes initial contact to the wafer in the bevel region. The slope of the bevel region will accordingly influence the compression dynamics of the pad, and therefore the effective force between the wafer and the pad in the following time interval. Due to the continuing movement of the pad relative to the wafer, this time interval translates into a wafer radius, so that the local pressure and thus the local polishing rate in an outer zone of the upper wafer surface 150 outer becomes a function of the wafer shape. Additionally, the bevel region will be polished during the CMP process, causing a shape modification as well.

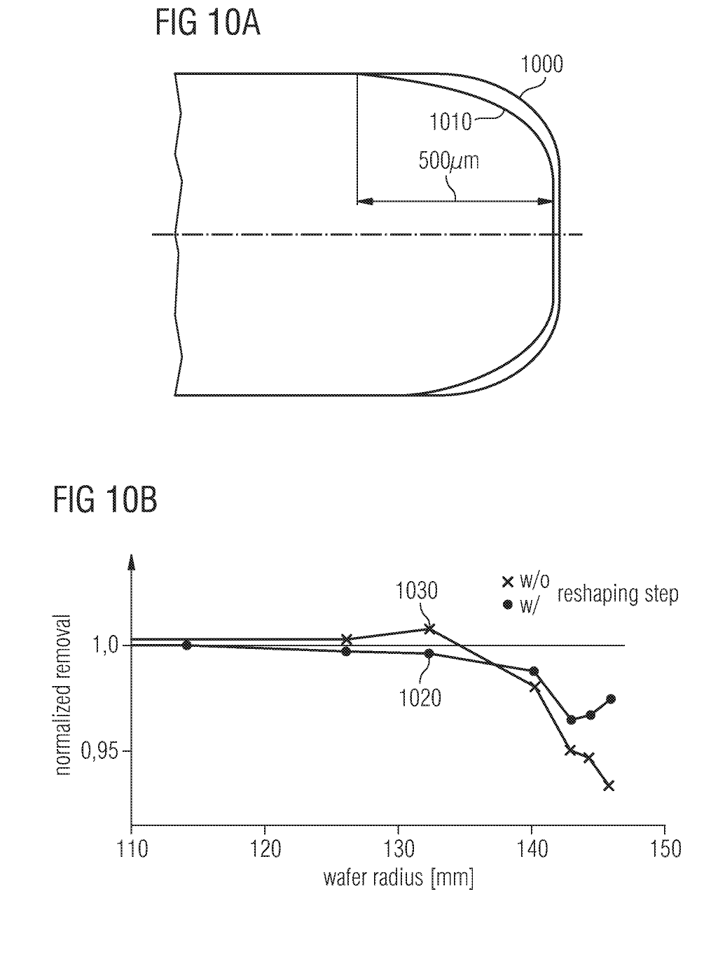

FIGS. 10a and 10b illustrate the effect of shape modification on a subsequent CMP step. One group of product wafers with a shape 1000, as illustrated in FIG. 10a, was divided into a reference subgroup and a reshaping subgroup. The wafers of the reshaping subgroup were subjected to a shaping process transforming the edge shape into the profile 1010, while the edge shape of the reference subgroup was not changed. The shaping step removed an amount of about 50 μm in the upper wafer bevel region extending up to 0.5 mm from the wafer edge, while less than 20 μm was removed in the lower wafer bevel region. Both subgroups were processed by a subsequent CMP step under volume manufacturing conditions and using the same process parameters. FIG. 10b illustrates the normalized removal of both subgroups as a function of wafer radius. As can be seen, the CMP removal of the reshaping subgroup deviates less from the wafer average 1.0 than the reference subgroup at the wafer edge, thus allowing to keep the removal within a given specification of +−5% of the average removal until the outermost measurement point located at 147 mm.

Another example of an interaction between the wafer shape and the process performance is a lithography process. A resist coated wafer is chucked, and a focus height measurement is commenced to determine the location of the upper wafer surface 150. A scanning probe, for example, a laser probe, may be used. When this probe enters the roll off region, and the bevel region, the wafer surface will deviate from the horizontal course, causing errors in determining the focus height. Additionally, the chucking force applied from the wafer backside 180 will deform the wafer, and this deformation will be influenced by the wafer shape. Therefore, the wafer shape will determine the area of the wafer, for which the resist coating can be maintained within the available focus window during the exposure process.

As a last, but not exhaustive example, in a dry etching process, a plasma is formed above the wafer surface 150, for example, using the wafer as one electrode. The wafer shape has a direct influence on the electrical fields at the wafer edge, as well as the gas flow and partial pressures in the wafer edge region, especially if a cooling gas is used. This may lead to non-uniformities at the wafer edge in etch rate, etch selectivity, CD values, and/or alignment of the etched features (for example, tilted contact holes).

FIG. 2 illustrates a wafer shape before and after performing a reshaping process. The upper wafer shape before reshaping 200 is transformed into the upper wafer shape after reshaping 210. The thickness 220 of the layer removed during the reshaping process can be defined through the parameterization procedure described above along the line between the wafer surface point and the reference point 290. The region of reshaping may extend from the outer edge of the wafer until an inner end 230, 230′. In one implementation the inner end 230, 230′ may have a distance of approximately 0.5 mm from the outer edge of the wafer, and, for example, the roll off region may be excluded from the reshaping. In a further implementation, the apex of the wafer or parts of it may not exhibit removal during the reshaping.

It is to be understood, that some manufacturing processes (like those described above) are not only sensitive to the wafer shape, but may also actively contribute to a modification of the wafer shape as a side effect. The reshaping process performs this modification in an intentional, controlled and reproducible manner.

The reshaping process transforms the lower wafer shape before reshaping 240 into a lower wafer shape after reshaping 250 in a similar manner. The thickness of the removed portion may be the same for the upper and lower wafer shapes, or may be different, including the case that the upper or lower shape is not modified at all during the reshaping process. In an implementation, the reshaping transforms a round type wafer into a blunt type wafer (as illustrated in FIG. 2 for the upper bevel) or vice versa (not illustrated). In a different implementation, a first blunt type shape 240 is transformed into a second blunt type shape 250 (as illustrated in FIG. 2 for the lower bevel) with a different facet angle.

The reshaping process can be a polishing process, a plasma etching process, a wet etching process or an electrochemical etching process. Suitable polishing tools are available from various suppliers, while plasma etching tools also have configurations to remove portions of the wafer edge selectively to the wafer center. Spin etching tools can also be configured to apply the etching chemistries selectively to the wafer edge. In order to achieve a significant shape modification, a minimum removal thickness of 1 μm in at least a portion of the wafer edge region is required, for example, a removal around 10 μm and above lead to noticeable effect in most of the shape sensitive unit processes described above. In one implementation, for example, a thickness of about 50 μm was removed, but also values exceeding 100 μm are feasible to practice embodiments. The removal amount for reshaping is higher than the amount removed in edge defect removal processes, in which the removal is generally limited to an amount effective to promote the release of the defects from the wafer surface. The removal values given include any layers deposited onto the bevel regions, which may also contribute to shape modifications observed during the course of processing steps.

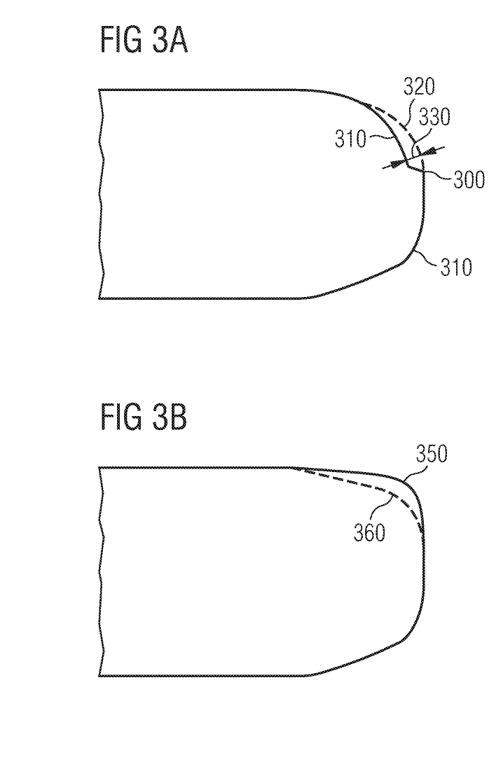

The process steps used to manufacture integrated circuits on the wafer also can modify the shape of the wafer edge considerably. These shape modifying processes include, but are not limited to, chemical mechanical polishing processes (CMP), reactive ion etching (RIE) processes, chemical and physical vapor deposition processes (CVD, PVD), wet etching processes, and spin on processes. FIGS. 3a and 3b illustrate exemplary modifications induced by such processes. FIG. 3a illustrates the shape of a wafer before (320) and after (310) a first shape modifying process. In the upper portion of the wafer edge, wafer material is excessively removed, and may lead to a step 300 in the shape. Such shapes have been observed, for example, after RIE processes, and may be caused by a local plasma-related erosion. Sharp shape features like the step 300 may lead to yield problems later, for example, through break off of wafer material or layers deposited onto such features at a later process step. Wafer chucking failure may also be caused by such features. Step heights around 30 μm have been observed, so that removal of these features require a removal in excess of this step height, that is, 30 μm in this case.

FIG. 3b illustrates a shape modifying process of additive character, for instance from a deposition process. A deposited layer changes the wafer edge shape from a shape 360 before the process to a shape 350 after the process. The deposited material may be of the same composition as a layer deposited onto the wafer surface 150 within the same process step, or may be of different composition, like, for example, a reaction byproduct being selectively deposited onto the wafer edge. The deposited material may also be a combination of materials deposited in two or more process steps. The FIGS. 3a, 3b describe a shape modification of an upper portion of the shape, however, in other cases the lower portion of the shape is as well or even exclusively modified.

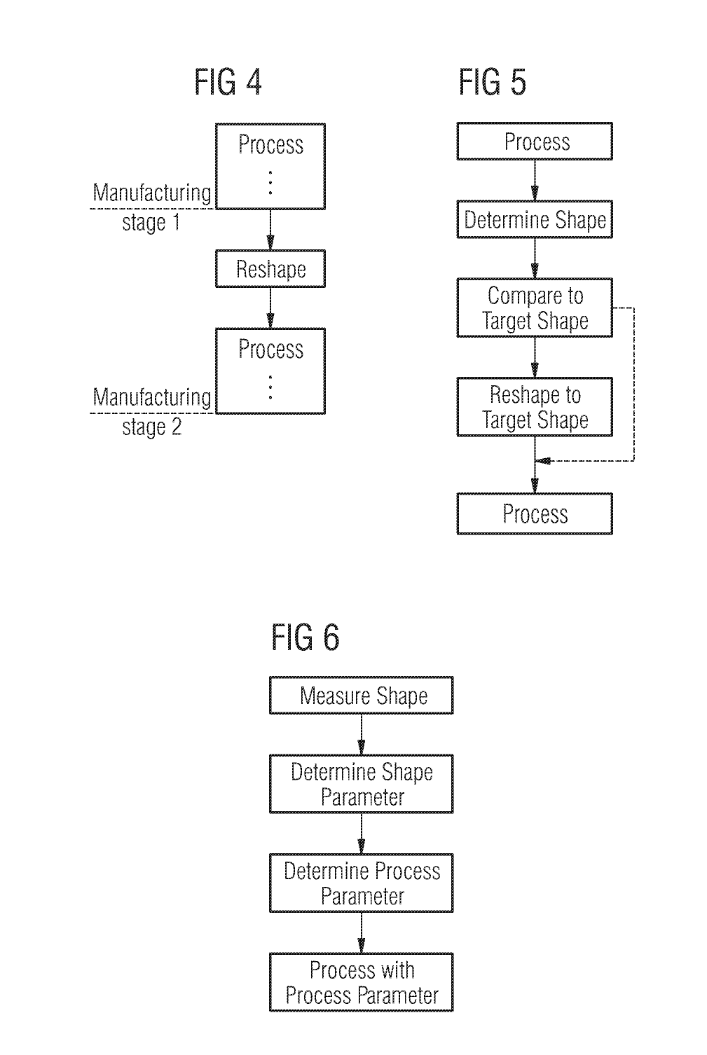

FIG. 4 illustrates a flow diagram of one embodiment. The wafer is processed to a first manufacturing stage. This processing may include a series of processing steps and generates a structure on the wafer. The processing may also modify the initial first shape of the wafer. In a following reshaping step the shape of the wafer is changed to a second shape. Then, further processing is performed on the wafer to a second manufacturing stage. This second stage may be the final stage of processing the wafer, or may be a stage, at which another reshaping step is performed. The process performance (as measured, for example, as component yield) of the further processing is influenced by the shape of the processed wafer. CMP processes, lithographic exposure, and RIE show a process performance influenced by the wafer shape, as described above. The region, in which the process performance is influenced, may be the extreme edge region of a width of a few millimeters, but may as well extend several centimeters towards the wafer center, as observed, for example, in the case of CMP. The reshaping step may in one implementation compensate for a shape modification introduced by the processes to achieve the first manufacturing stage, thereby recovering the initial shape. It may also be a different shape being found suitable for processing the wafer to the second manufacturing stage.

In another aspect, the reshaping step may transform the wafer shape into a different shape, for which the subsequent process steps show an improved overall performance compared to the performance without the reshaping step. For example, the front end of line (FEOL) processes for generating the active devices may require a different wafer shape than the back end of line (BEOL) processes for manufacturing the metallization levels. The reshaping step would in such case be performed between the FEOL and the BEOL. In one implementation, wafer shape types are toggled between round type and blunt type by creating a facet with a predetermined facet angle within or removing a facet from the bevel region.

A more detailed process flow according to one embodiment is illustrated in FIG. 5. After the first process at least one parameter of the wafer shape is determined. The at least one shape parameter is then compared to a target shape in order to determine the reshaping process. Then, the determined reshaping process is performed in order to achieve a target shape. After this, a second process step is performed. The process performance of the second process is influenced by the wafer shape as described above. In a further implementation, one result of the comparison of the measured profile to the target profile is that no reshaping is required, and the reshaping step is skipped, as indicated by the dashed line.

The determination of the wafer shape may be a measurement performed by an imaging device, for example, a digital imaging device, which records a spatial image of the wafer edge. Other methods to determine the wafer shape may include a light beam scanned over and reflected by the wafer edge, or a probe, like a stylus or a capacitive probe brought in contact or in vicinity of the wafer edge and moved across the region, in which the shape is to be determined. In an implementation, a shape parameter specific to the supplier of the wafer is taken.

FIG. 6 illustrates a process flow according to another implementation. In a first step, the wafer shape is measured, for example, with one of the methods and devices described above. From this measured data, at least one shape parameter is determined. Examples for the parameter are facet angle and facet length, extreme values of the curvature, distance of the surface from the projected surfaces 150′, 180′ (or the local curvature at this location) or in a predetermined distance from the outer wafer edge 110, among others. In an implementation, the shape parameter is determined from the information about the wafer supplier, since wafers from certain wafer suppliers are known to have specific shapes. In a further step, the determined shape parameter is used to select at least one process parameter for a subsequent processing step. The selection of the at least one process parameter may include selecting one or more parameters in a process recipe, selecting one process recipe from a plurality of recipes, adding process steps to a process recipe, and/or choosing a process tool for a subsequent process step. In a following step, the wafer is processed using the selected at least one process parameter.

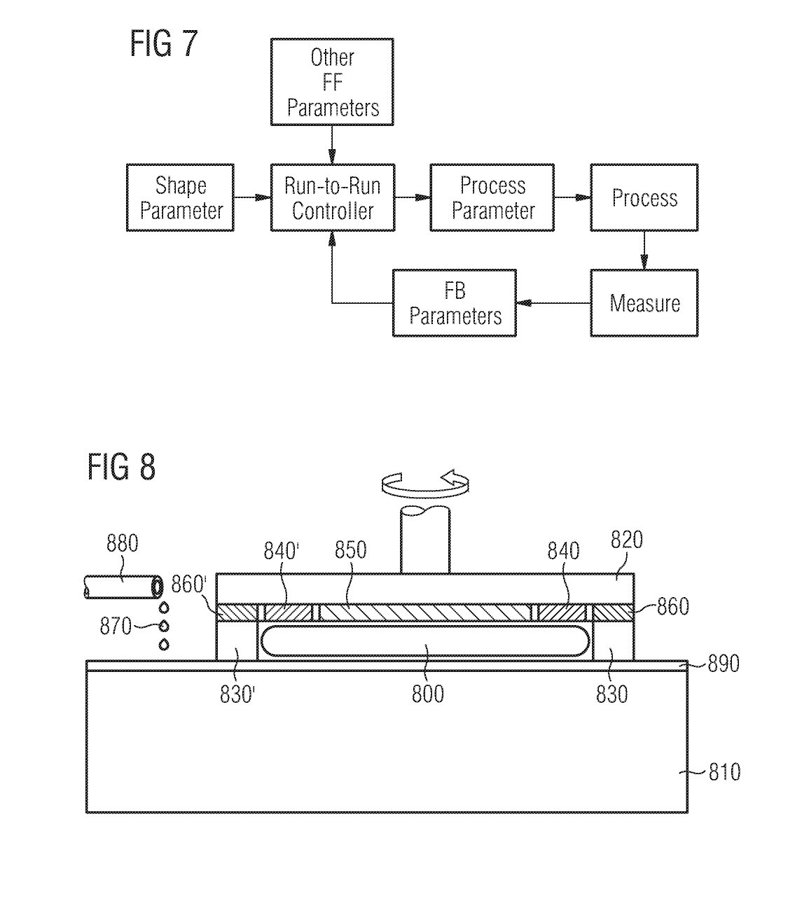

In FIG. 7, a run-to-run controlling scheme is illustrated using wafer shape information. Along with other feed forward information related to a wafer to be processed (for example, pre-process metrology data, or logistic information from previous steps or about the wafer) at least one shape parameter derived from one of the above described methods or devices is fed into a run-to-run controller. Based on the predetermined controller rules and a current controller state, at least one process parameter is determined to process the wafer, and processing of the wafer is commenced using this at least one process parameter. The result of the processing is determined through a subsequent post-process metrology step. This post-process metrology data or post-process feed-back values calculated from it are fed back into the run-to-run controlling system, and may cause the controller state and/or the controller rules to be updated. The run-to-run controller may include one controller state for all wafer shape parameters or a plurality of controller state, each applicable to a subset of wafer shape parameters. The same set of controller rules may as well be applicable independent of the wafer shape parameter, or different sets of controller rules may be defined for different sets of shape parameters.

One specific example of how to process a wafer within the process flows of FIGS. 6 and 7 is depicted in FIG. 8 showing a setup of a CMP process. A wafer 800 is pressed by a wafer carrier against a polishing pad 890 attached on a polishing platen 810. The wafer carrier includes a retaining ring 830, 830′ and a rigid plate 820 and is configured to provide rotary motion. Pressure elements 840, 840′, 850 are configured to provide local pressure to respective zones of the wafer 800. Pressure element 850 applies pressure mainly to the center portion of the wafer 800, and may include further sub elements (not illustrated). Pressure elements 840, 840′ apply pressure mainly to the edge portion of the wafer 800, and as well may include further sub elements (not illustrated). A further pressure element 860, 860′ is configured to apply pressure to the retaining ring. In specific wafer carrier configurations, a down force may be applied to the rigid plate 820 as a whole, and the local pressures applied to the different zones of the wafer and the retaining ring may be a combination of the down force and the pressures applied by the pressure elements. The pressure elements 840, 840′, 850 and its sub elements may have a circular symmetric arrangement with the axis of symmetry located at the wafer center.

During polishing, the polishing pad 890 is moved relative to the wafer (for example, by a rotary platen movement), and a polishing slurry 870 is dispensed to the pad 890 through a slurry dispenser 880, thus leading to a removal of material from the wafer surface contacting the polishing pad 890 at a given removal rate. This setup allows to compensate for the removal rate non-uniformities observed especially at the wafer edge. In cases, where a non-uniform removal is targeted (for example, if the incoming thickness before polishing is non-uniform), the setup also allows to adjust to a non-uniform removal during polishing accordingly.

As described above, the wafer shape has been found to be one important parameter to determine the removal rate at the wafer edge, so that this setup together with the various implementations allows to compensate for wafer shape related effects as well as incoming thickness variations in CMP processes. For example, the pressure applied to the retaining ring 830, 830′ and the different zones 840, 840′, 850 of the wafer 800 may be derived from a pre-process wafer shape measurement or a run-to-run controller like described above.

With the increasing automation of the manufacturing of integrated circuits, it is desirable to combine a plurality of related functionalities into a single process tool. In the case of wafer reshaping, it is desirable to configure a wafer shaping apparatus in such a way that it is capable to receive wafer material of differing incoming shape and provide wafer material of like target shape as outgoing shape.

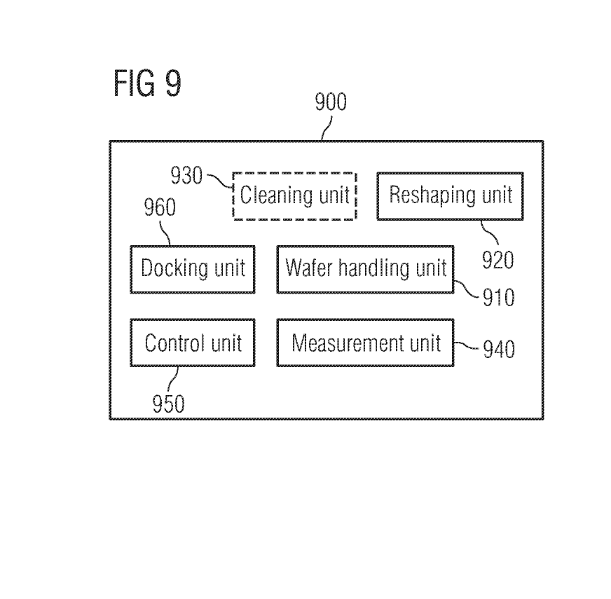

The setup of FIG. 9 provides such an apparatus according to one embodiment. The docking unit 960 is capable to receive wafer material for processing within the wafer shaping apparatus. For example, the docking unit 960 can receive multiple lots, like from a overhead transportation system, and interfaces mechanically with the wafer handling unit 910, which is configured to transport the wafers between the units of the wafer shaping apparatus 900. The sequence of wafer movements between the units and the processing information for the units are controlled by a control unit 950. A shaping unit 920 performs the shape modification process and includes a device for polishing, dry or wet etching, or electrochemical etching the wafer edge. Optionally, a separate cleaning unit 930 may be included in the wafer shaping apparatus 900, or may form part of the shaping unit 920. The cleaning unit is configured to clean the wafer from residues of the shaping process, and may include a rinsing and/or brush cleaning module, as well as a drying module, like a spin-rinse-dryer or a marangoni dryer.

The measurement unit 940 illustrated in FIG. 9 as part of the wafer shaping apparatus 900 includes a device to perform a shape measurement of a wafer as described above. The shape measurement data may be transmitted to the control unit 950. The wafer may be transferred to the measurement unit 940 before and/or after processing in the shaping unit 920. A comparison of the shape data with a target shape may be performed, and the processing as well as the sequence of movement of a specific wafer between units may depend on the comparison result. For example, a second (rework) shaping process may be automatically performed if the measured shape after the first shaping process differs from the predetermined target shape by an amount higher than a predetermined rework threshold.

Although specific embodiments have been illustrated and described herein, it will be appreciated by those of ordinary skills in the art that a variety of alternative and/or equivalent implementations may be substituted for the specific embodiments and implementations illustrated and described without departing from the scope of the present invention. This application is intended to cover any adaptations or variations of the specific embodiments discussed herein. Therefore it is intended that this invention be limited only by the claims and the equivalents thereof.

What is claimed is:

1. A method of manufacturing an integrated circuit comprising:
processing a wafer with an edge region having a first shape to a first manufacturing stage;
reshaping the wafer to transform the wafer edge region into a second shape; and
processing the wafer to a second manufacturing stage.

2. The method of claim 1, wherein the second shape is different from the first shape.

3. The method of claim 1, wherein reshaping the wafer comprises removing material from the wafer edge region.

4. The method of claim 3, wherein material is removed in a region up to 0.5 mm from the wafer edge.

5. The method of claim 1, wherein reshaping the wafer comprises one of the group comprising polishing, plasma etching, electrochemical etching, and wet etching the wafer edge region.

6. The method of claim 1, wherein reshaping the wafer comprises removing material of at least 1 μm thickness from the wafer edge region.

7. The method according to claim 3, wherein removing material comprises removing material selectively from an upper surface of the wafer edge region.

8. The method according to claim 1, wherein reshaping the wafer comprises:
determining the shape of the wafer edge region;
comparing the determined shape to a target shape to obtain a comparison result; and
removing material from the wafer in dependence from said comparison result.

9. The method of claim 1, wherein processing the wafer to a first manufacturing stage comprises one process of the group comprising chemical mechanical polishing, deposition, and plasma etching.

10. The method of claim 1, wherein processing the wafer to a first manufacturing stage modifies the shape from the first shape to a third shape, and wherein the second shape differs from the first shape less than the third shape.

11. The method of claim 10, wherein the second shape is approximately equal to the first shape.

12. The method of claim 1, wherein processing the wafer to a second manufacturing stage comprises one process of the group comprising chemical mechanical polishing, lithographical exposure, and plasma etching.

13. The method of claim 1, wherein processing the wafer to a first manufacturing stage comprises forming semiconductor devices of the integrated circuit, and wherein processing the wafer to a second manufacturing stage comprises forming a metallization level of the integrated circuit.

14. A method of manufacturing an integrated circuit on a wafer comprising:
determining the wafer shape to obtain a shape parameter;
selecting a process parameter for processing the wafer in dependence from the shape parameter; and
processing the wafer using the process parameter.

15. The method of claim 14, wherein selecting the process parameter comprises entering the shape parameter into a run-to-run controller configured to provide process parameters for said processing.

16. The method of claim 14, wherein the shape parameter is determined from a measurement of the shape of an upper side of the wafer.

17. The method of claim 14, wherein processing the wafer comprises chemical mechanical polishing.

18. The method of claim 17, wherein the process parameter comprises a parameter determining a pressure value applied to the wafer during the chemical mechanical polishing of the wafer, and wherein the pressure value is applied to an edge portion of the wafer.

19. The method according to claim 17, wherein the process parameter determines a pressure value applied to a retaining ring.

20. A method for increasing component yield in a semiconductor manufacturing process, the method comprising:
forming a structure on a semiconductor wafer;
reshaping the semiconductor wafer with the structure to form a reshaped wafer; and
forming another structure on the reshaped wafer.

21. A wafer shaping apparatus comprising
a shape measurement unit configured to determine a shape parameter from a shape of a wafer bevel;
a shaping unit configured to form a wafer edge region into a predetermined shape;
control means for receiving the shape parameter from the shape measurement unit and for sending process parameters to the shaping unit,
a docking unit configured to accept a wafer container; and
a wafer handling unit configured to transfer wafers between the shape measurement unit, the shaping unit and the docking unit,
wherein the control means is configured to determine the process parameters in dependence from the shape parameter.

22. The apparatus of claim 21, wherein the shaping unit comprises one of the group comprising a plasma etching unit, a polishing unit, a electrochemical etching unit and a wet etching unit.

23. The apparatus of claim 21, wherein the control means is configured to receive a target profile, and wherein the control means is configured to determine the process parameter in dependence from the target profile.

24. The apparatus of claim 21, further comprising a wafer cleaning unit.

25. The apparatus of claim 21, wherein the shape measurement unit comprises one of the group comprising a digital imaging device, a laser scanning device, a stylus, and a capacitive probe.
